(19) United States
(12) Patent Application Publication
(10) Pub. No.: US 2026/0369712 A1
(43) Pub. Date: Nov. 19, 2026

(54) SYSTEMS AND METHODS FOR ELECTRICAL ENERGY STORAGE CELL TEMPERATURE MEASUREMENTS

(71) Applicant: Instagrid GmbH, Ludwigsburg (DE)

(72) Inventors: Raphael Zürner, Ludwigsburg (DE); Philipp Gutknecht, Ludwigsburg (DE)

(21) Appl. No.: 19/731,302

(22) Filed: Jul. 6, 2026

Related U.S. Application Data
(63) Continuation of application No. PCT/EP2025/054698, filed on Feb. 21, 2025.

(30) Foreign Application Priority Data
Mar. 26, 2024 (EP) 24166253.5

(51) Int. Cl. H01M 10/48; G01K 1/14; G01K 1/16; G01K 3/00; G01R 19/165; G01R 31/364

(52) U.S. Cl. CPC H01M 10/486; G01K 1/14; G01K 1/16; G01K 3/005; G01R 19/16542; G01R 31/364

(57) ABSTRACT

It is disclosed a circuit comprising: electrical energy storage cell(s) (EESCs); a circuit board comprising an electrically isolating substrate; an electrically conductive terminal (ECT) connected between EESCs and the circuit board (ECT being configured to concurrently facilitate (i) an electrical connection between EESC(s) and CB and (ii) a transfer of heat from the EEC(s) to the electrically isolating substrate of CB; and a temperature sensor mounted to a surface of CB and configured to measure a temperature of EESC(s) based on a temperature of the electrically isolating substrate of CB. The temperature sensor is electrically isolated from ECT. Heat is allowed to flow from EESC(s) to the temperature sensor via ECT and the electrically isolating substrate. Other aspects such as methods are also disclosed.

### CROSS-REFERNECE TO RELATED APPLICATIONS

The present application claims priority to and the benefit of European Patent Application No. 24166253.5, filed on Mar. 26, 2024, the content of which is incorporated herein by reference in its entirety.

### BACKGROUND

### Description of the Related Art

Battery cell packs are often used to power electronic devices. The temperature of the battery cells thereof may be monitored during use of the same. Long pinned or wired temperature sensors are often used for the temperature measurements. These temperature sensors are typically mounted in a way that a battery cell temperature is coupled strongly therewith. In this regard, each temperature sensor is manually placed at a position near the battery cell(s). Thereafter, the pins or wires of the temperature sensor may be soldered to a respective pad on a circuit board. In effect, the manufacturing process of the battery cell device is relatively manually intensive, inefficient, time consuming and costly.

### SUMMARY

The present disclosure concerns a circuit comprising: one or more electrical energy storage cells; a circuit board comprising an electrically isolating substrate; an electrically conductive terminal connected between at least one of the electrical energy storage cells and the circuit board (the electrically conductive terminal being configured to concurrently facilitate (i) an electrical connection between the at least one of the electrical energy storage cells and the circuit board and (ii) a transfer of heat from the at least one of the electrical energy storage cells to the electrically isolating substrate); and a temperature sensor mounted to a surface of the circuit board and configured to measure a temperature of the at least one of the electrical energy storage cells based on a temperature of the electrically isolating substrate of the circuit board. The temperature sensor is electrically isolated from the electrically conductive terminal. Heat is allowed to flow from the at least one of the electrical energy storage cells to the temperature sensor via the electrically conductive terminal and the electrically isolating substrate.

The present disclosure also concerns implementing systems and methods for operating a circuit. The methods comprise: using a conductive terminal to concurrently facilitate (i) a measurement of a voltage of an electrical energy storage cell and (ii) a transfer of heat from the electrical energy storage cell to a conductive plane provided within a circuit board; allowing the heat to flow from the electrical energy storage cell to a substrate of the circuit board via the conductive terminal and the conductive plane; and using a temperature sensor, which is mounted to a surface of the circuit board, to measure a temperature of the electrical energy storage cell based on a temperature of the substrate of the circuit board. The temperature sensor is electrically isolated from the conductive terminal and the conductive plane.

### BRIEF DESCRIPTION OF THE DRAWINGS

The present solution will be described with reference to the following drawing figures, in which like numerals represent like items throughout the figures.

FIG. 1 provides a perspective view of a power supply.

FIG. 2 provides an illustrative block diagram of the power supply shown in FIG. 1.

FIG. 3 provides a perspective view of an energy module of the power supply shown in FIG. 1.

FIG. 4 provides an assembly view of the energy module shown in FIG. 3.

FIG. 5 provides an illustrative block diagram of a circuit in the energy module shown in FIGS. 3-4.

FIGS. 6-7 provide illustrations of an energy module that are useful for understanding a conventional placement of a temperature sensor therein.

FIGS. 8-10 provide illustrations that are useful for understanding an energy module circuit with a surface mount temperature sensor in accordance with the present solution.

FIG. 11 provides an illustration of another energy module circuit with a surface mount temperature sensor in accordance with the present solution.

FIG. 12 provides an illustration of an energy module circuit with an electrically isolating and thermally conductive member connected between a surface mount temperature sensor and a conductive terminal.

FIGS. 13A-13B (collectively referred to herein as “FIG. 13”) provide illustrations of thermal isolation features.

FIG. 14 provides an illustration showing an energy module circuit having a plurality of voltage sensors and temperature sensors.

FIG. 15 provides a flow diagram of an illustrative method for operating a circuit.

### DETAILED DESCRIPTION

The present solution is described with reference to the attached figures. The figures are not drawn to scale and they are provided merely to illustrate the instant solution. Several aspects of the present solution are described below with reference to example applications for illustration. It should be understood that numerous specific details, relationships, and methods are set forth to provide a full understanding of the present solution. One having ordinary skill in the relevant art, however, will readily recognize that the present solution can be practiced without one or more of the specific details or with other methods. In other instances, well-known structures or operations are not shown in detail to avoid obscuring the present solution. The present solution is not limited by the illustrated ordering of acts or events, as some acts may occur in different orders and/or concurrently with other acts or events. Furthermore, not all illustrated acts or events are required to implement a methodology in accordance with the present solution.

It should also be appreciated that the terminology used herein is for the purpose of describing particular embodiments only and is not intended to be limiting of the present solution. As used herein, the singular forms “a”, “an” and “the” are intended to include the plural forms as well, unless the context clearly indicates otherwise. Furthermore, to the extent that the terms “including”, “includes”, “having”, “has”, “with”, or variants thereof are used in either the detailed description and/or the claims, such terms are intended to be inclusive in a manner similar to the term “comprising.”

Further, unless otherwise defined, all terms (including technical and scientific terms) used herein have the same meaning as commonly understood by one of ordinary skill in the art to which this solution belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As noted above, conventional manufacturing processes of battery cell devices are relatively manually intensive, inefficient, time consuming and costly. Thus, there is a need for a battery cell design that facilitates an improved manufacturing process. The present solution is directed to a novel temperature sensor design that allows for an improved manufacturing process for battery devices with a cell temperature monitoring feature.

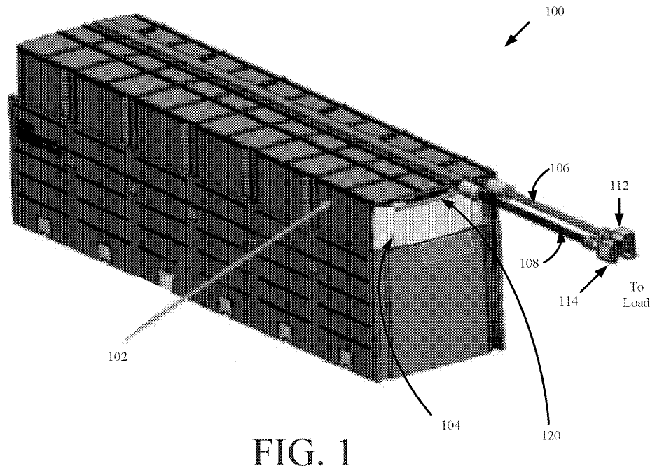

FIG. 1 provides an illustration of a power supply 100 which may be portable or otherwise mobile. The power supply 100 may have a size and weight to allow a single individual to carry the same with relative ease and/or to allow the same to be carried in a backpack or other bag. Power supply 100 may be connected in series or parallel with other power supplies to form a power supply unit.

Power supply 100 is generally configured to supply electric power to a load (not shown in FIG. 1). The load can include any electronic device that needs to be supplied power. Such loads can include, but are not limited to, another power supply, communication devices, media devices, golf carts, electric appliances, computing devices, and/or professional or home energy storage systems.

As shown in FIG. 1, the power supply 100 comprises a housing 102 in which a plurality of energy modules 104 are housed. Each energy module 104 is generally configured to convert direct current (DC) outputs from internal electrical energy storage cells into an alternating current (AC) output of the energy module. The electrical energy storage cells can include, but are not limited to, battery cells and/or super capacitors. The energy modules 104 are electrically connected to each other via insulated wires 106, 108. In this way, the AC outputs of the energy modules are combined or otherwise summed together to produce the AC output power of the power supply 100. More specifically, the energy modules 104 are connected in series in a controllable manner to supply different voltages at the output of the power supply 100. Connectors 112, 114 are provided at the distal ends of insulated wires 106, 108 to provide a means to connect the output of the power supply 100 to the load.

In some uses, more than one instance of the power supply 100 may be coupled together to obtain a larger capacity power supply and/or a multi-voltage power supply. Such plurality of instances of the power supply 100 may, for example, be enclosed in a common housing (not shown in FIG. 1). It is further possible to obtain multi-phase power supplies using multiple instances of the power supply 100. It shall be appreciated that such arrangements may further benefit from a reliable thermal monitoring of the electrical energy storage cells which are packed together.

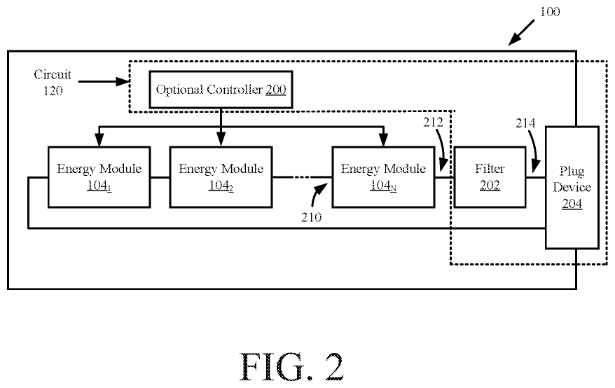

Operation of the energy modules 104 may be controlled using an internal circuit 120. An illustrative technique for controlling the energy modules will now be discussed in relation to the block diagram of FIG. 2. The energy modules are referred to in FIG. 2 by reference numbers 104₁, 104₂, . . . 104_{N}. The energy modules 104₁, 104₂, . . . 104_{N} may be collectively referred to herein as energy modules 104. N is an integer equal to or greater than one.

As shown in FIG. 2, circuit 120 may comprise an optional controller 200, a filter 202 and a plug device 204. Controller 200 may reside external to the power supply 100 in some scenarios in which the power supply 100 comprises part of a grid. The grid can include a plurality of power supplies that are connected to each other and controlled by a unit controller. Controller 200 is shown internal to the power supply 100 for ease of illustration and explanation of the system operations. However, the present solution is not limited to the shown configuration. The plug device 204 may include the wires (e.g., wires 106, 108 of FIG. 1), connectors (e.g., connectors 112, 114 of FIG. 1), and/or other components to facilitate the supply of power to a load.

The controller 200 is configured to selectively activate and deactivate the energy modules 104 for causing the power supply 100 to deliver AC power to the load with the correct voltage, current and frequency. The controller 200 is connected to each of the energy modules 104₁, 104₂, . . . 104_{N} so that the energy modules can be controlled individually thereby. The controller 200 is configured to selectively transition each energy module between a battery mode and a bypass mode. When an energy module is in its battery mode, the internal electrical energy storage cells are switched into the circuit such that they are connected between terminals 210, 212 thereof. As such, a voltage output from the electrical energy storage cells is provided at terminal 210 and 212. In contrast, when the energy module is in a bypass mode, the internal electrical energy storage cells are bypassed such the terminals 210, 212 are directly shortened to each other. In effect, no voltage from the electrical energy storage cells is provided at terminal 210 or 212 of the energy module.

Particularly, an energy module may provide the following operation modes: a Hi-Z (high impedance) mode in which module output is set to a high-impedance state (e.g., associated with none of the switches in the module being turned ON); a bypass mode in which the energy module is not contributing any battery voltage, but letting the current flow via it (e.g., via both low-side switches of the H-bridge being turned ON); a conducting+mode in which the electrical energy storage cells are connected to the module output in a given polarity; and a conducting mode in which the electrical energy storage cells are connected to the module output in an opposite polarity as compared to the conducting+mode.

By successively transitioning the energy modules from the bypass mode to the battery mode, the combined output voltage of the energy modules 104 can be increased in steps. Similarly, by successively transitioning the energy modules from the battery mode to the bypass mode, the combined output voltage of the energy modules 104 can be decreased in steps. The combined output voltage can be changed by an amount equal to the output voltage V_{M} of one energy module. Thus, the combined output voltage V_{C} can vary between zero volts and N times V_{M} Volts (i.e., 0 Volts<V_{C}<N·V_{M} Volts). For obtaining finer transition between the V_{M} steps, at least one energy module can be operated in a pulse-width-modulation (PWM) mode with time varying duty-cycle. The combined output voltage V_{C} can be smoothed by filter 202 so as to produce a voltage signal on line 214. The voltage signal on line 214 may have sinusoidal characteristics, DC signal characteristics or other waveform characteristics.

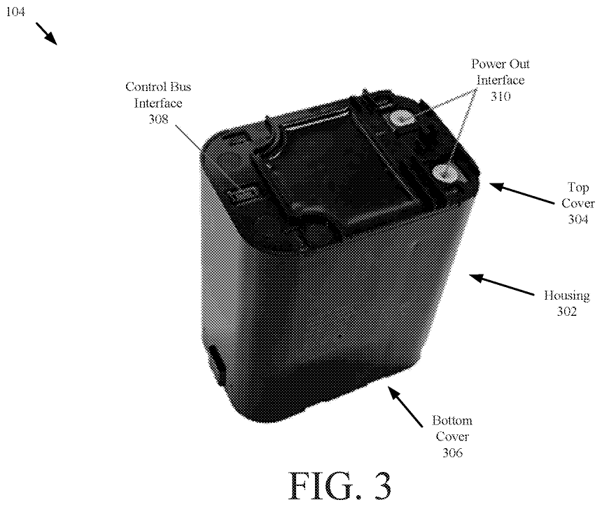

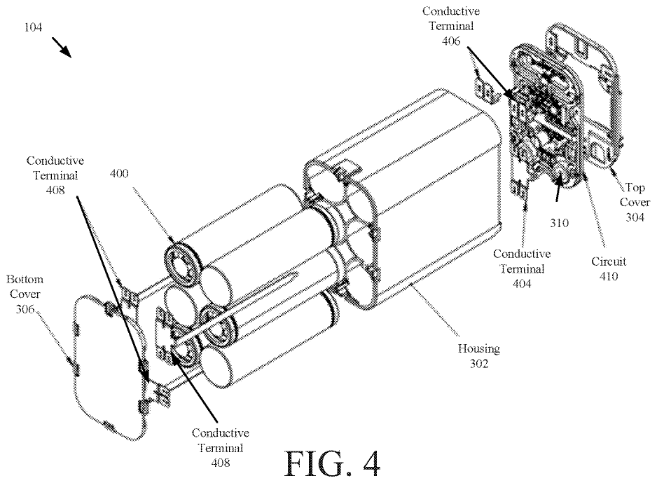

FIG. 3 provides an illustration of an energy module 104. An assembly view of the energy module 104 is provided in FIG. 4. Energy modules 104 of FIGS. 1 and 104₁, 104₂, . . . , 104_{N} of FIG. 2 may be the same as or similar to the energy module shown in FIG. 3.

Energy module 104 comprises a housing 302 in which electrical energy storage cells 400 are housed so as to maintain certain positions relative to each other. The electrical energy storage cells 400 can be arranged in two rows of three cells as shown in FIGS. 3-4. The present solution is not limited in this regard. The electrical energy storage cells can have a different arrangement than that shown in FIGS. 3-4. Any number of electrical energy storage cells can be provided in the energy module in accordance with a given application. Each electrical energy storage cell may include, but is not limited to, a lithium-ion cell. Hence, the energy module 104 may comprise electrical energy storage cells which are in the form of an electrical battery, capacitor or supercapacitor, their likes or their combinations. The electrical energy storage cell, or lithium-ion cell, may have a cylindrical shape as shown or another shape (e.g., a rectangular shape) not shown.

A top cover 304 and a bottom cover 306 are provided for the housing 302. The covers 304, 306 may be configured to provide an environment seal with the housing 302. The environmental seal may be facilitated by gaskets (not visible or shown in FIGS. 3-4) compressed between the covers 304, 306 and the housing's sidewalls. The module 104 also comprises a power out interface 310.

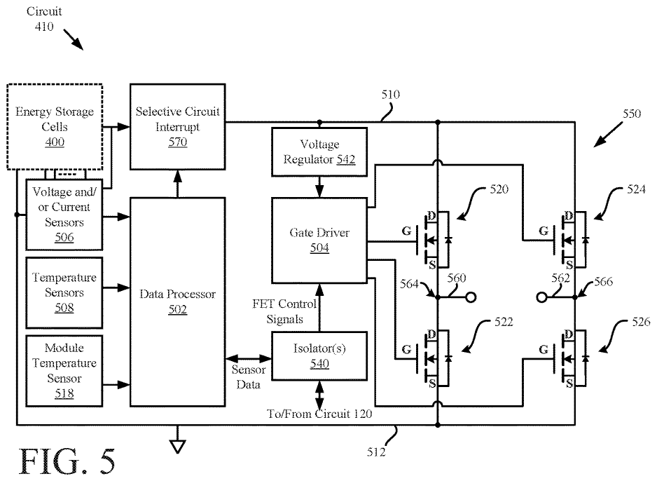

The safe and reliable operation of the energy module 104 may require the constant monitoring of each electrical energy storage cell 400 to detect when its current, voltage and/or temperature fall outside of defined operating range(s). This monitoring may be achieved using a circuit 410 that may also be housed in the housing 302. Conductive connectors 404, 406, 408 are provided to connect the electrical energy storage cells 400 to the circuit 410 for at least voltage measurements. In some non-limiting examples, the conductive connectors 404 may also be used for leading operationally generated heat away from the circuit 410 (e.g., heat generated by switching elements) preferably away from the module 104. Alternatively or in addition, some non-limiting examples, the circuit 410 may be arranged such that the storage components 400 are also used for leading operationally generated heat away from the circuit 410. For example, a thermal coupling (e.g., passive and/or active, such as gas or fluid cooled) may be provided between the circuit 410 and one or more of the storage components 400. Alternatively or in addition, as some non-limiting examples, the power out interface 310 may be used for leading operationally generated heat away from the circuit 410. For example, conductive connectors 404 are realized in electrically conductive materials such as metal. Usually electrical conductors are also good thermal conductors. This can be leveraged to also act as heat sinks or heat pipes for transporting operationally generated heat (e.g., heat generated when the switching components are conducting current) away from the circuit 410. It shall be appreciated that either alone or in any combination, these measures can make the module 400 more compact, and in some cases also allow hermetically sealing of the module 400. This can further result in a more compact system which uses one or more of such modules 400. These measures can also result in a module and/or system comprising one or more modules that do not require active cooling (e.g., a fan or any other types of additional component or medium used for cooling). A block diagram of circuit 410 is provided in FIG. 5.

As shown in FIG. 5, circuit 410 comprises voltage and current sensors 506 connected to the electrical energy storage cells 400. These sensors 506 are configured to measure the voltage and/or current of each electrical energy storage cell. Circuit 410 may also comprise temperature sensors 508 and a module temperature sensor 518. Each temperature sensor 508 is configured to measure a temperature of one or more electrical energy storage cells, while the module temperature sensor 518 is configured to measure an internal temperature of the energy module. More specifically, the temperature sensor senses the temperature close to the power stage consisting of FETs 520, 522, 522, 526. These sensor measurements are communicated from the sensors 506, 508, 518 to the data processor 502 for processing and measurement acquisition. The data processor 502 can perform operations to communicate sensor measurements as sensor data to circuit 410, and/or perform operations to analyze the sensor measurements to determine if certain criteria is met. For example, if a parameter measurement falls outside of defined range at a given time or for a certain amount of time, then the data processor 502 causes the circuit interrupt 570 to transition from a closed state to an open state such that the power input and output of the energy module 104 is turned off. The parameter measurement can include a voltage measurement, a current measurement or a temperature measurement.

The circuit 410 also comprises a gate driver 504 and a switching circuit, shown here in a non-limiting manner as transistor active bridge 550. Switching circuit comprises at least one switching element. As some non-limiting examples, the switching circuit may be realized as a bridge topology comprising switching elements, e.g., as a full H-bridge or a half H-bridge. The switching circuit may be in any form e.g., which facilitates electrical connection of one or more of the storage components 400 to the electrical connection 560 and/or 562. The switching circuit or the transistor active bridge circuit 550 is supplied a DC voltage waveform from the electrical energy storage cells 400. As such, the transistor active bridge circuit 550 is connected to electrical energy storage cells 400 via input lines 510, 512. The transistor active bridge circuit 550 is also connected between a pair of output lines 560, 562. The output lines 560, 562 are connected to the power interface 210/212 of FIGS. 2 and/or 310 of FIG. 3.

The transistor active bridge circuit 550 includes a plurality of switches, shown in this example as field-effect transistors (FETs) 520, 522, 524, 526 of an N-channel type. Each of the FETs may comprise a metal-oxide semiconductor FET (MOSFET). Alternatively, other kinds of switches are also possible, such as but not limited to bipolar junction transistor (BJT) or insulated gate bipolar transistor (IGBT) based switches, or even relays. Each FET 520, 522, 524, 526, in this example, has three (3) terminals respectively defined as a source S, a gate G and a drain D. An electrical path is provided from the source to the drain of each FET 520, 522, 524, 526. This path is generally referred to herein as the source-drain path. A source-drain path of first FET 520 is connected in series with a source-drain path of the second FET 522. The series connected transistor pair 520, 522 form a first series transistor combination that is connected across the input lines 510, 512. A source-drain path of the third FET 524 is connected in series with a source-drain path of the fourth FET 526 to form a second series transistor combination connected across the input lines 510, 512.

The transistor active bridge 550 can have an output defined by output lines 560, 562. A first one of the output lines 560 can be connected to the first series combination 520, 522 at an interconnection point 564 between the first and the second field-effect transistors 520, 522. A second one of the output lines 562 can be connected to the second series combination 524, 526 at an interconnection point 566 between the third and fourth field-effect transistors 524, 526.

Gate driver 504 is provided for driving the gate G of each FET 520, 522, 524, 526. In this regard, the gate driver is configured to supply a voltage to the gate G of each FET at certain times for switching the FET to its “on” state or “off” state. The gate driver is also configured to stop supplying the voltage to the gate G of the FET at certain times for switching the FET to its “on” state or “off” state. Gate driver circuits are well known. Known or to be known gate driver circuit can be used here. In some cases, the gate driver 504 may be realized as different circuits for each or some of the FETs 520, 522, 524, 526.

When the gate driver 504 communicates gate control signals to the FETs 520, 526, the FETs 520, 526 will be biased and switch to their “on” states, thus providing voltage from the energy storage cells 400 at the output lines 560, 562. In effect, current may flow between the drain D and source S of these FETs to supply a load connected between the output lines 560, 562. The FETs 520, 526 transition back to their “off” states when the gate control signals are no longer being output from the gate driver circuit. Similarly, when the gate driver 504 communicates gate control signals to the FETs 522, 524, the FETs 522, 524 will be biased and switched to their “on” states, thus providing voltage from the energy storage cells 400 at the output lines 560, 562 but in the opposite polarity as compared to the “on” state of the FETs 520 and 526. In effect, current may flow between the drain D and source S of these FETs 522, 524 to supply a load connected between the output lines 560, 562. It shall be appreciated that the load will experience current in opposite polarity in case FETs 522, 524 are “on”, as compared to the case when FETs 520, 526 are “on”. The FETs 522, 524 transition back to their “off” states when the gate control signals are no longer being output from the gate driver. The gate driver may be configured to prevent the two FETs in each series pair 520/526 and 522/524 from being closed simultaneously or concurrently.

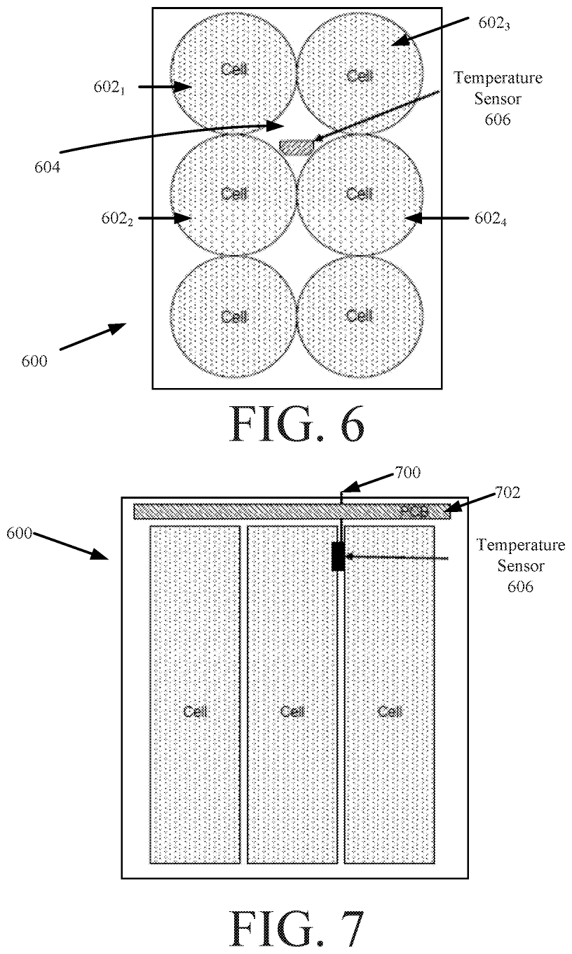

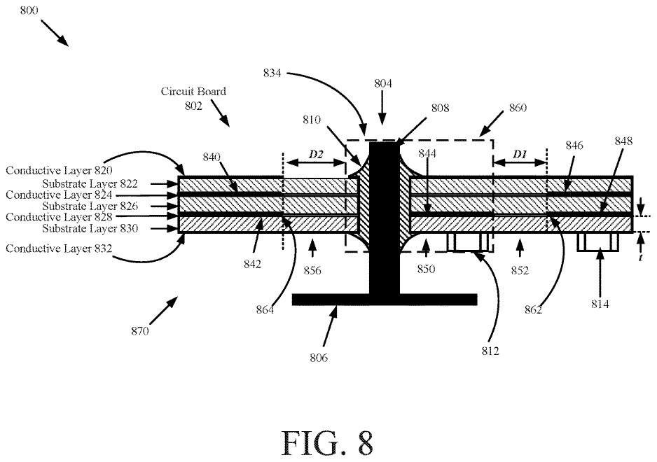

The manufacturing process of conventional energy modules is relatively manually intensive, inefficient, time consuming and costly. This is at least partially due to the use of wire or long pin temperature sensors for cell temperature measurements. FIGS. 6-7 provide illustrations that are useful for understanding the conventional temperature sensor architecture of an energy module. This conventional architecture comprises a temperature sensor 606 that is mounted so as to extend into an empty space 604 between electrical energy storage cells 602₁, 602₂, 602₃, 602₄ and so as to be located proximate to electrical energy storage cells 602₂, 602₄. In this way, the temperature of electrical energy storage cells 602₂, 602₄ are coupled with the temperature sensor 606. For example, the temperature sensor 606 can include a through-hole-technology (THT) sensor. The pins 700 of the temperature sensor 606 are soldered to a circuit board 702. The placement of the temperature sensor 606 amongst the electrical energy storage cells and the soldering of the temperature sensor 606 to the circuit board 702 are manually performed during a manufacturing process of the energy module 600.

The present solution provides a novel temperature sensor architecture for an energy module that eliminates the need for a long pinned temperature sensor in an energy module and therefore also eliminates the manual process. This is achieved through the use of a surface mount (SMT) sensor for measuring cell temperature. The SMT sensor is more suitable for an automated manufacturing process for the energy module with a minimized cost and time.

It should be noted that the SMT temperature sensor mounted on a circuit board may be more influenced by temperature sources on the same circuit board rather than by the electrical energy storage cells. Moreover, a farther proximity of an SMT sensor from the electrical energy storage cells may cause reduction in temperature measurement capability or reliability. Thus, the present solution addresses this issue by maximizing the thermal conductivity from the SMT temperature sensor to the battery cell and minimizes the thermal conductivity from SMT temperature sensor to other temperature sources on the circuit board. The manner in which this is accomplished will become evident as the discussion progresses. However, in general, this is achieved with SMT temperature placement, circuit board layout, use of cell voltage sense connections, and/or other optional aspects to improve or reduce thermal conductivity in one or other direction.

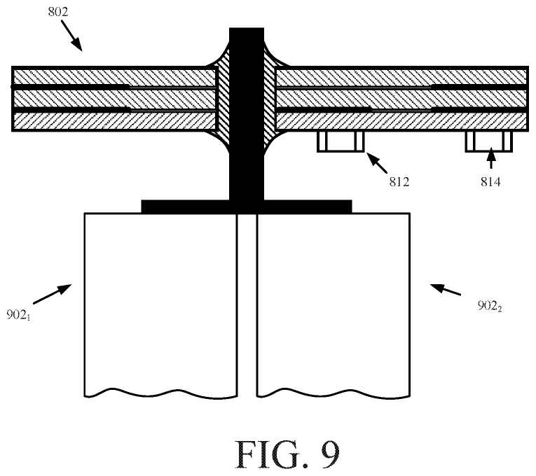

FIG. 8 provides a perspective view of an illustrative architecture for an internal circuit 800 of an energy module. The energy module can include, but is not limited to, energy module 104 of FIG. 1, energy module 104₁, . . . , 104_{N} of FIG. 2, or the energy module of FIG. 3. The circuit 410 of FIGS. 4-5 can be the same as or similar to circuit 800 of FIG. 8.

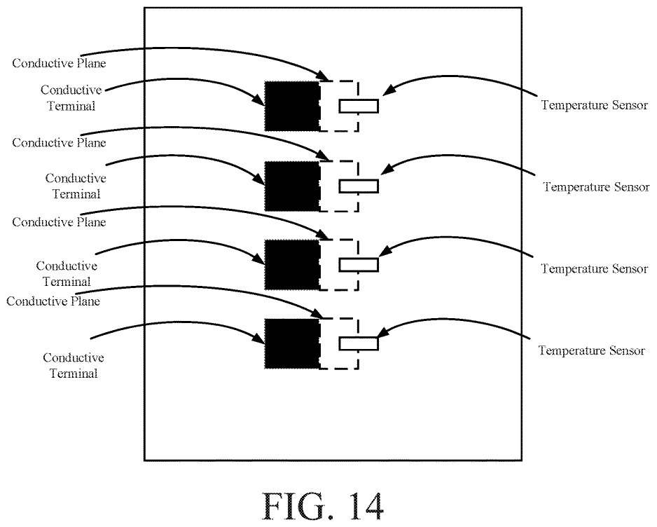

As seen in FIG. 8, internal circuit 800 will be described in relation to a single conductive terminal 804 and a single temperature sensor 812 for simplicity of discussion. Conductive terminal 804 may be configured to facilitate voltage sensing and measurements. In other words, the main purpose of the conductive terminal 804 may be to provide electrical signals at the internal circuit 800. However, it should be understood that internal circuit 800 can include any number of conductive terminals and temperature sensors selected in accordance with a particular application. For example, as shown in a top view of FIG. 14, the circuit can include four conductive terminals and four temperature sensors. The present solution is not limited to the particulars of FIG. 14. The following discussion is sufficient for understanding the architecture for each pair of components 804, 812 provided with an internal circuit of an energy module.

It should also be noted that a data processor (e.g., data processor 502) is electrically connected to the conductive terminal 804 and the temperature sensor 812 so that voltage and temperature measurements can be received thereby. The data processor is configured to detect when voltage and temperature measurements fall outside of pre-specified ranges. The data processor and these electrical connections are not shown in FIG. 8 for ease and simplicity of illustration.

The conductive terminal 804 comprises a distal end 806 that can be welded or otherwise coupled to the electrical energy storage cells. The conductive terminal 804 can include, but is not limited to, conductive terminal 404 of FIG. 4. The temperature sensor 812 can include, but is not limited to, a surface mount thermistor or other surface mount temperature sensor.

In addition to the components 804 and 812, circuit 800 comprises other electronic component(s) 814 mounted on a multi-layer circuit board 802. The electronic component(s) can include, but are not limited to, resistor(s), capacitor(s), inductor(s), amplifier(s), filter(s), selective circuit interrupt(s) (e.g., selective circuit interrupt 570 of FIG. 5), voltage regulator(s) (e.g., voltage regulator 542 of FIG. 5), isolator(s) (e.g., isolators 540 of FIG. 5), processor(s) (e.g., data processor 502 of FIG. 5), gate driver(s) (e.g., gate driver 504 of FIG. 5), a transistor active bridge circuit (e.g., transistor active bridge circuit 550 of FIG. 5).

Multi-layer circuit board 802 comprises substrate layers 822, 826, 830 and conductive layers 820, 824, 828, 832. The exact number of layers which the circuit board 802 has is not essential or limiting to the present teachings. Substrate layers 822, 826, 830 are formed of the same or different dielectric material. Each of the conductive layers 820, 824, 828, 832 may comprise one or more conductors 840, 842, 844, 846, 848 formed thereon. Conductors 840, 842, 844, 846, 848 can include, but are not limited to, traces. It should be noted that the present solution is not limited to the conductive layer architecture shown in FIGS. 8-10. For example, conductive layer 820 may be less than or greater than distance D2 from a conductive connection 810. Additionally or alternatively, conductive layer 820 may cover all or a portion of a surface of substrate layer 822, and/or comprise a conductive trace connecting the conductive connection 810 to another component residing elsewhere on the substrate layer 822.

A through-hole pad 834 is formed through the circuit board 802. A connection member 808 of the conductive terminal 804 extends through the through-hole pad 834. Solder may be used to couple the connection member 808 to the circuit board 802 and provide an electrical connection between the conductive terminal 804 and conductor 844. This connection is referred to as a conductive connection 810. Conductive connection 810 can include, but is not limited to, a solder joint.

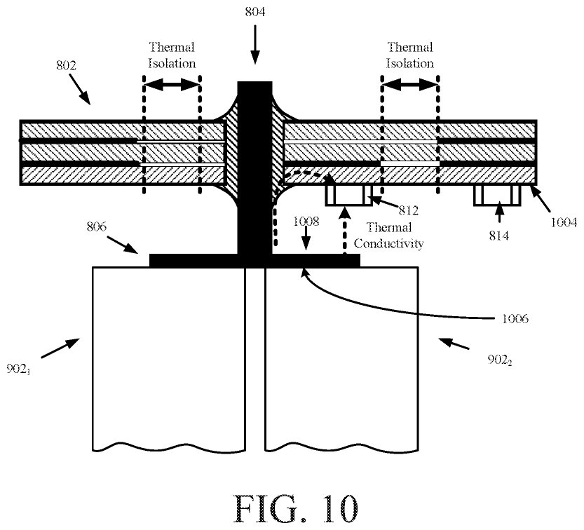

The temperature sensor 812 is mounted on a side 870 of the circuit 800 which faces the electrical energy storage cells 902₁, 902₂ when the module is assembled as illustrated in FIG. 9. The temperature sensor 812 is located proximate to the conductive terminal 804 and conductor 844 so that it can detect the temperature of the electrical energy storage cells 902₁, 902₂ via the conductive terminal 804. Since the distal end 806 of the conductive terminal 804 is conductively connected directly to the electrical energy storage cells 902₁, 902₂, the conductive terminal 804 also provides relatively good thermal conductivity suitable for cell temperature measurements, while providing the main purpose of relatively good electrical conductivity suitable for cell voltage measurements. Hence, an electrical component having the main purpose of establishing electrical connection is further leveraged to obtain more accurate temperature measurements in a non-contact fashion with a device-under-monitoring. It shall be appreciated that the “device-under-monitoring” in this case would be one or more of the electrical energy storage cells.

It should be noted that the temperature sensor 812 is electrically not directly connected to the conductive terminal 804. An electrical isolation between the temperature sensor 812 and the conductive terminal 804 is facilitated by the design of the multi-layer circuit board 802, the relative positions of the two components 804, 812, and the relative positions of components 812, 844. First, the thickness t of the substrate layer 830 is selected to be relatively thin. For example, this thickness t is selected to be less than 0.2 mm in some scenarios to ensure that conductive layers 828, 832 are located relatively close to each other. Second, a conductive trace or plane 844 is disposed on conductive layer 828 (i) so as to be electrically connected to the conductive terminal 804 via conductive connection 810 and (ii) so that it resides directly in proximity to (e.g., above) the temperature sensor 812. The size, shape and/or material of the conductive plane 844 can be selected to maximize thermal conductivity to the temperature sensor 812. For example, the conductive plane 844 may substantially overlap or extend the region occupied by the temperature sensor 812 on the layer 832. The conductive plane 844 is formed of a conductive material configured to provide thermal conductivity with the conductive terminal 804. The conductive material can include, but is not limited to, copper, tin, gold or other materials or alloys. The data processor may be electrically connected to the conductive terminal via the conductive plane. Thus, the conductive plane 844 may be leveraged also as a thermal conductor for the temperature sensor 812 besides performing its main task of routing or establishing electrical connection of the conductive terminal 804 with other electrical components. This can save space and costs. This can also simplify the production process, e.g., assembly of the energy module 104. By preventing a leaded temperature sensor, deformed sensor leads can be avoided in production. This can enhance production yield of assembled modules.

The substrate layer 830 is formed of a material configured to provide thermal conductivity and electrical isolation between conductive connection 810 and temperature sensor 812 and between conductive plane 844 and temperature sensor 812. The temperature sensor 812 is disposed on the circuit board 802 at a location that provides a gap 850 between itself and the connection member 808 of the conductive terminal 804. The size of gap 850 is selected to ensure that the temperature sensor is electrically isolated from the conductive connection 810. Thus, the structure can allow a good thermal contact to the temperature sensor 812 despite being electrically isolated from the conductive terminal 804.

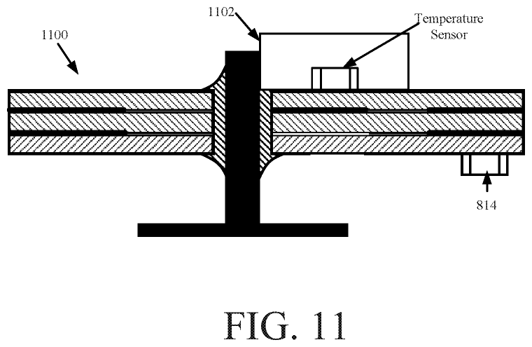

In FIG. 8, area 860 includes the conductive connection 810 and the temperature sensor 812. Area 860 is thermally isolated from other electrical components of circuit 800. The other electrical components include conductors 840, 842, 846, 848 and electronic component(s) 814. A gap 852 is provided between area 860 and components 814, 846, 848. The size and shape of gap 852 is selected so that area 860 is located at least a given distance D1 from a closest edge 862 of each conductor 846, 848. A gap 856 is also provided between area 860 and conductors 840, 842. The size and shape of gap 856 is selected so that area 860 is located at least a given distance D2 from a closest edge 864 of each conductor 840, 842. Distances D1 and D2 are selected to ensure that there is a minimized amount of thermal conductivity between area 860 and components 814, 840, 842, 846, 848 of circuit 800. An illustration is provided in FIG. 10 which shows the areas of thermal isolation and conductivity of circuit 800.

As seen in FIG. 10, the temperature sensor 812 is mounted on the surface 1004 of the circuit board 802 facing the electrical energy storage cells 902₁, 902₂. The temperature sensor 812 may be configured to output a signal comprising a value corresponding to a measured temperature of the electrical energy storage cells 902₁, 902₂.

A thermal conductivity from the temperature sensor 812 to the electrical energy storage cells 902₁, 902₂ is greater than a thermal conductivity from the temperature sensor 812 to other temperature sources (e.g., 814, 840, 842, 844, 846 and/or 848) disposed on the circuit board 802. The other temperature sources may optionally comprise a processing circuit disposed on the circuit board. The processing circuit can include, but is not limited to, electronic component(s) such as resistor(s), capacitor(s), inductor(s), amplifier(s), filter(s), selective circuit interrupt(s), voltage regulator(s), isolator(s), processor(s), gate driver(s), and/or a transistor active bridge circuit(s).

Heat is allowed to flow from the electrical energy storage cells 902₁, 902₂ (e.g., towards) to a first surface 1006 of a distal end 806 of the electrically conductive terminal 804, and from an opposing second surface 1008 of the distal end 806 of the electrically conductive terminal 804 in an electrically isolated manner (e.g., through the air) to the temperature sensor 812. The first surface 1006 of the distal end 806 being adjacent to and in contact with the electrical energy storage cells 902₁, 902₂. The second surface 1008 of the distal end 806 facing and being spaced apart from the temperature sensor 812. The temperature sensor may reside between the distal end 806 of the electrically conductive terminal 804 and the conductive plane 844 disposed on the electrically isolating substrate 830. The distal end 806 of the electrically conductive terminal 804 may comprise a first elongate member extending generally perpendicular to a second elongate member (e.g., 844) that passes through the circuit board 802.

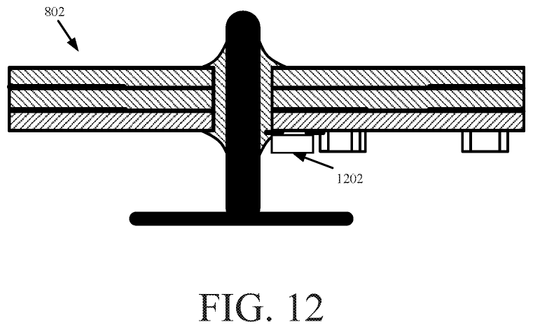

The present solution is not limited to the architecture shown in FIGS. 8-10. The temperature sensor could alternatively reside on the opposite side 1100 of the circuit board which faces away from the electrical energy storage cells as shown in FIG. 11. This alternative placement of the temperature sensor enables accessibility thereto after soldering a conductive terminal to the circuit board. After soldering the conductive terminal to the circuit board, the temperature sensor and the conductive connection could be thermally connected and still electrically isolated by any suitable material 1102. This material 1102 can include, but is not limited to, a potting material, thermal glue and/or thermal paste.

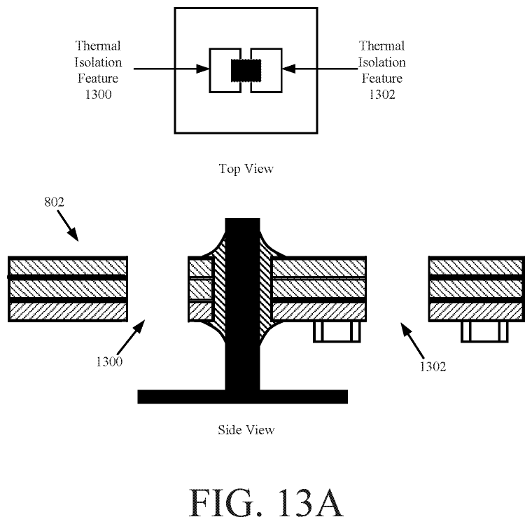

Alternatively or additionally, the thermal conductivity from the conductive connection 810 to the temperature sensor may be improved using one or more electrically isolating and thermally conductive member 1202 as shown in FIG. 12. The electrically isolating and thermally conductive member 1202 can include, but is not limited to, a thermal jumper, thermal paste, thermal glue and/or a thermal potting material. Member 1202 may be connected between the conductive connection 810 and/or the temperature sensor. Any known or to be known electrically isolating and thermally conductive member can be used here.

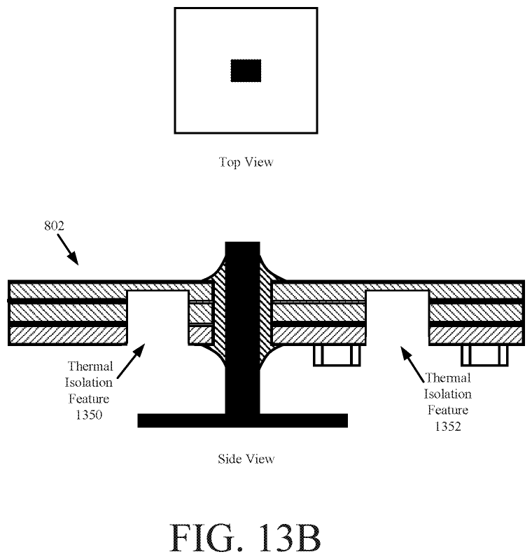

Alternatively or additionally, the circuit board can be milled or otherwise processed so that thermal isolation features are formed as voids therein to provide thermal isolation between area 860 and conductors 840, 842, 846, 848. The thermal isolation features 1300, 1302, 1350, 1352 can extend all the way through the circuit board as shown in FIG. 13A or extend only partially through the circuit board as shown in FIG. 13B.

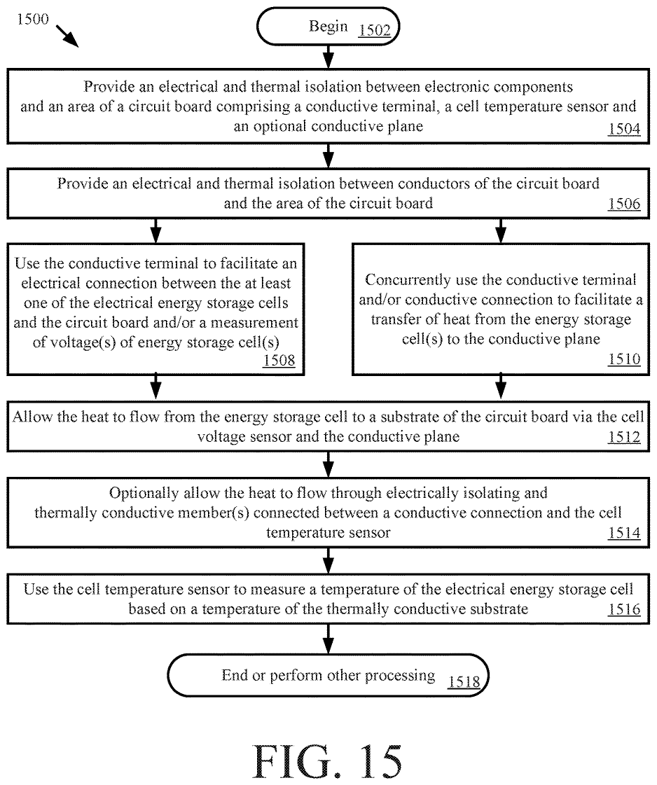

FIG. 15 provides a flow diagram of an illustrative method 1500 for operating a circuit. Method 1500 begins with 1502 and continues with 1504 where an electrical and thermal isolation is provided between electronic component(s) of the circuit (e.g., component(s) 814 of FIG. 8) and an area (e.g., area 860 of FIG. 8) of a circuit board (e.g., circuit board 802 of FIG. 8) comprising a conductive terminal (e.g., conductive terminal 804 of FIG. 8), a temperature sensor (e.g., temperature sensor 812 of FIG. 8) and an optional conductive plane (e.g., conductive plane 844 of FIG. 8). The thermal isolation may be provided by one or more gaps (e.g., gaps 852, 856 of FIG. 8, thermal isolation features 1300, 1302 of FIG. 13A, and/or thermal isolation features 1350, 1352 of FIG. 13) located on and within the circuit board between the other electronic components and the area. The gap(s) may be filled with a gas (e.g., air) or a portion of at least one material forming the circuit board or any other material providing thermal isolation. An electrical and thermal isolation is also provided in 1506 between conductors (e.g., conductors 840, 842, 846, 848 of FIG. 8) of the circuit board and the area of the circuit board comprising the cell voltage sensor, the temperature sensor and the optional conductive plane.

In 1508, the conductive terminal is used to facilitate (i) an electrical connection between the at least one of the electrical energy storage cells and the circuit board and/or (ii) a measurement of voltage(s) of electrical energy storage cell(s) (e.g., electrical energy storage cell 902₁ and/or 902₂ of FIG. 9). As such, the conductive terminal is electrically connected to a data processor (e.g., data processor 502 of FIG. 5) so that the voltage measurement can be analyzed to detect when the electrical energy storage cell(s) are not operating as expected (e.g., the cell voltage falls outside an acceptable range of voltage values). This electrical connection between the conductive terminal and the data processor may be made using a conductor or a conductive plane disposed on a substrate layer of the circuit board.

The conductive terminal is also used in 1510 to facilitate a transfer of heat from the electrical energy storage cell(s) to the conductive plane provided within the circuit board. 1510 may also optionally involve using a conductive connection, provided between the conductive terminal and the circuit board, to further facilitate the transfer of heat from the electrical energy storage cell to the conductive plane.

In 1512, heat is allowed to flow from the electrical energy storage cell to a substrate (e.g., substrate layer 830 of FIG. 8) of the circuit board via the conductive terminal, conductive connection and/or the conductive plane. The heat may also optionally be allowed to flow in 1514 through an electrically isolating and thermally conductive member (e.g., member 1202 of FIG. 12) that is connected between the conductive terminal and the temperature sensor.

In 1516, the temperature sensor (e.g., temperature sensor 812 of FIG. 8) is used to measure a temperature of the electrical energy storage cell(s) based on a temperature of the substrate of the circuit board. The temperature sensor is mounted to a surface of the circuit board so as to be electrically isolated from the conductive terminal and the conductive plane. The conductive plane is disposed on a first side of the substrate layer and the temperature sensor is disposed on an opposite second side of the substrate layer at a location overlapped by the conductive plane.

Subsequently, method 1500 continues to block 1518 where it ends or other operations are performed. The other operations can include, but are not limited to, returning to block 1502.

Although the present solution has been illustrated and described with respect to one or more implementations, equivalent alterations and modifications will occur to others skilled in the art upon the reading and understanding of this specification and the annexed drawings. In addition, while a particular feature of the present solution may have been disclosed with respect to only one of several implementations, such feature may be combined with one or more other features of the other implementations as may be desired and advantageous for any given or particular application. Thus, the breadth and scope of the present solution should not be limited by any of the above described scenarios. Rather, the scope of the present solution should be defined in accordance with the following claims and their equivalents.

Without excluding further possible embodiments, certain example embodiments are summarized in the following clauses:

Clause 1: A circuit comprising: one or more electrical energy storage cells; a circuit board comprising an electrically isolating substrate; an electrically conductive terminal connected between at least one of the electrical energy storage cells and the circuit board, the electrically conductive terminal being configured to concurrently facilitate (i) an electrical connection between the at least one of the electrical energy storage cells and the circuit board and (ii) a transfer of heat from the at least one of the electrical energy storage cells to the electrically isolating substrate; and a temperature sensor mounted to a surface of the circuit board and configured to measure a temperature of the at least one of the electrical energy storage cells based on a temperature of the electrically isolating substrate of the circuit board. The temperature sensor is electrically isolated from the electrically conductive terminal. Heat is allowed to flow from the at least one of the electrical energy storage cells to the temperature sensor via the electrically conductive terminal and the electrically isolating substrate.

Clause 1A. The circuit of clause 1, wherein the temperature sensor is mounted on the surface of the circuit board facing the electrical energy storage cells, and/or the temperature sensor is configured to output a signal comprising a value corresponding to a measured temperature of the electrical energy storage cells.

Clause 1B. The circuit of any of the preceding clauses, wherein a thermal conductivity between (e.g., from) the temperature sensor and the electrical energy storage cells is greater than a thermal conductivity between (e.g., from) the temperature sensor and other temperature sources (e.g., heat sources) disposed on the circuit board. The other temperature sources or heat sources may optionally comprise a processing circuit disposed on the circuit board. The processing circuit can include, but is not limited to, electronic component(s) such as resistor(s), capacitor(s), inductor(s), amplifier(s), filter(s), selective circuit interrupt(s), voltage regulator(s), isolator(s), processor(s), gate driver(s), and/or a transistor active bridge circuit(s).

Clause 1C. The circuit of any of the preceding clauses, wherein: the heat is allowed to flow from the electrical energy storage cells to (e.g., towards) a first surface of a distal end of the electrically conductive terminal, and from an opposing second surface of the distal end of the electrically conductive terminal in an electrically isolated manner (e.g., through the air) to the temperature sensor; the first surface of the distal end being adjacent to and in contact with the electrical energy storage cells; and/or the second surface of the distal end facing and being spaced apart from the temperature sensor.

Clause 1D. The circuit of any of the preceding clauses, wherein the temperature sensor resides between the distal end of the electrically conductive terminal and the conductive plane disposed on the electrically isolating substrate.

Clause 1E. The circuit of any of the preceding clauses, wherein the distal end of the electrically conductive terminal comprises a first elongate member extending generally perpendicular to a second elongate member that passes through the circuit board.

Clause 2: The circuit of any of the preceding clauses, further comprising a conductive connection provided between the electrically conductive terminal and the circuit board that is configured to further facilitate the transfer of heat from the at least one of the electrical energy storage cells to a conductive plane disposed on the electrically isolating substrate.

Clause 3: The circuit of any of the preceding clauses, wherein the conductive connection provides a path by which heat is allowed to further flow to the temperature sensor.

Clause 4: The circuit of any of the preceding clauses, further comprising an electrically isolating and thermally conductive member connected between the conductive connection and the temperature sensor.

Clause 5: The circuit according to any of the preceding clauses, wherein a conductive plane is disposed on a first side of the substrate and the temperature sensor is disposed on an opposite second side of the substrate at a location overlapped by the conductive plane.

Clause 6: The circuit according to any of the preceding clauses, further comprising at least one other electronic component that is thermally isolated from an area of the circuit board comprising the conductive terminal, the temperature sensor and a conductive plane disposed on the substrate.

Clause 7: The circuit according to any of the preceding clauses, further comprising one or more gaps located on and within the circuit board between the area and the at least one other electronic component.

Clause 8: The circuit according to any of the preceding clauses, wherein the one or more gaps are filled with a gas or other thermally isolating material comprises a portion of at least one material forming the circuit board.

Clause 9: The circuit according to any of the preceding clauses, wherein a plurality of conductors of the circuit board are thermally isolated from an area of the circuit board comprising the conductive terminal, the temperature sensor and a conductive plane disposed on a substrate.

Clause 10: The circuit according to any of the preceding clauses, further comprising a data processor electrically connected to the conductive terminal and the temperature sensor, and configured to detect when voltage and temperature measurements fall outside of pre-specified ranges.

Clause 11: A method for operating a circuit, comprising: using a conductive terminal to concurrently facilitate (i) a measurement of a voltage of an electrical energy storage cell and (ii) a transfer of heat from the electrical energy storage cell to a conductive plane provided within a circuit board; allowing the heat to flow from the electrical energy storage cell to a substrate of the circuit board via the conductive terminal and the conductive plane; and using a temperature sensor, which is mounted to a surface of the circuit board, to measure a temperature of the electrical energy storage cell based on a temperature of the substrate of the circuit board, wherein the temperature sensor is electrically isolated from the conductive terminal and the conductive plane.

Clause 12: The method according to clause 11, further comprising using a conductive connection, provided between the conductive terminal and the circuit board, to further facilitate the transfer of heat from the electrical energy storage cell to the conductive plane.

Clause 13: The method according to any of the preceding method clauses, further comprising allowing the heat to further flow through the conductive connection.

Clause 14: The method according to any of the preceding method clauses, further comprising allowing the heat to further flow through an electrically isolating and thermally conductive member connected between the conductive connection and the temperature sensor.

Clause 15: The method according to any of the preceding method clauses, wherein the conductive plane is disposed on a first side of the substrate and the temperature sensor is disposed on an opposite second side of the substrate at a location overlapped by the conductive plane.

Clause 16: The method according to any of the preceding method clauses, further comprising providing a thermal isolation between other electronic components or conductors and an area of the circuit board comprising the conductive terminal, the temperature sensor and the conductive plane.

Clause 17: The method according to any of the preceding method clauses, wherein the thermal isolation is provided by one or more gaps located on and within the circuit board between the other electronic components or conductors and the area.

Clause 18: The method according to any of the preceding method clauses, wherein the one or more gaps are filled with a gas or comprises a portion of at least one material forming the circuit board.

Clause 19: The method according to any of the preceding method clauses, further comprising providing an electrical connection between the conductive terminal, the temperature sensor and a data processor of the circuit.

Clause 20: An arrangement (e.g., a circuit or system) comprising means for performing the steps of any of the above method clauses.

The breadth and scope of this disclosure should not be limited by any of the above-described example embodiments, but should be defined only in accordance with the following claims and their equivalents.

1. A circuit, comprising:
one or more electrical energy storage cells;
a circuit board comprising an electrically isolating substrate;
an electrically conductive terminal connected between at least one of the electrical energy storage cells and the circuit board, the electrically conductive terminal being configured to concurrently facilitate (i) an electrical connection between the at least one of the electrical energy storage cells and the circuit board and (ii) a transfer of heat from the at least one of the electrical energy storage cells to the electrically isolating substrate; and
a temperature sensor mounted to a surface of the circuit board and configured to measure a temperature of the at least one of the electrical energy storage cells based on a temperature of the electrically isolating substrate of the circuit board, wherein the temperature sensor is electrically isolated from the electrically conductive terminal;
wherein heat is allowed to flow from the at least one of the electrical energy storage cells to the temperature sensor via the electrically conductive terminal and the electrically isolating substrate.

2. The circuit according to claim 1, further comprising a conductive connection provided between the electrically conductive terminal and the circuit board that is configured to further facilitate the transfer of heat from the at least one of the electrical energy storage cells to a conductive plane disposed on the electrically isolating substrate.

3. The circuit according to claim 2, wherein the conductive connection provides a path by which heat is allowed to further flow to the temperature sensor.

4. The circuit according to claim 2, further comprising an electrically isolating and thermally conductive member connected between the conductive connection and the temperature sensor.

5. The circuit according to claim 1, wherein a conductive plane is disposed on a first side of the substrate and the temperature sensor is disposed on an opposite second side of the substrate at a location overlapped by the conductive plane.

6. The circuit according to claim 1, further comprising at least one other electronic component that is thermally isolated from an area of the circuit board comprising the conductive terminal, the temperature sensor and a conductive plane disposed on the substrate.

7. The circuit according to claim 1, wherein the area is spaced apart from the at least one other electronic component.

8. The circuit according to claim 7, wherein a space between the area and the at least one other electronic component is filled with a gas or comprises a portion of at least one material forming the circuit board.

9. The circuit according to claim 1, wherein a plurality of conductors of the circuit board are thermally isolated from an area of the circuit board comprising the conductive terminal, the temperature sensor and a conductive plane disposed on a substrate.

10. The circuit according to claim 1, further comprising a data processor electrically connected to the conductive terminal and the temperature sensor, and configured to detect when voltage and temperature measurements fall outside of pre-specified ranges.

11. A method for operating a circuit, comprising:
using a conductive terminal to concurrently facilitate (i) a measurement of a voltage of an electrical energy storage cell and (ii) a transfer of heat from the electrical energy storage cell to a conductive plane provided within a circuit board;
allowing the heat to flow from the electrical energy storage cell to a substrate of the circuit board via the conductive terminal and the conductive plane; and
using a temperature sensor, which is mounted to a surface of the circuit board, to measure a temperature of the electrical energy storage cell based on a temperature of the substrate of the circuit board, wherein the temperature sensor is electrically isolated from the conductive terminal and the conductive plane.

12. The method according to claim 11, further comprising using a conductive connection, provided between the conductive terminal and the circuit board, to further facilitate the transfer of heat from the electrical energy storage cell to the conductive plane.

13. The method according to claim 11, wherein the conductive plane is disposed on a first side of the substrate and the temperature sensor is disposed on an opposite second side of the substrate at a location overlapped by the conductive plane.

14. The method according to claim 1, further comprising providing an electrical connection between the conductive terminal, the temperature sensor and a data processor of the circuit.

15. An arrangement, comprising:
a circuit board;
an electrical energy storage cell;
a temperature sensor mounted to a surface of the circuit board and configured to measure a temperature of the electrical energy storage cell based on a temperature of a substrate of the circuit board; and
a conductive terminal configured to concurrently facilitate (i) a measurement of a voltage of the electrical energy storage cell and (ii) a transfer of heat from the electrical energy storage cell to a conductive plane provided within the circuit board;
wherein heat is allowed to flow from the electrical energy storage cell to the substrate of the circuit board via the conductive terminal and the conductive plane; and
wherein the temperature sensor is electrically isolated from the conductive terminal and the conductive plane.

16. The circuit according to claim 1, wherein the temperature sensor is mounted to the surface of the electrically isolating substrate of the circuit board so as to face inwards towards the electrical energy storage cells and be spaced apart from the electrically conductive terminal.

17. The circuit according to claim 16, wherein the temperature sensor is configured to measure a temperature of the electrically isolating substrate of the circuit board, wherein the measured temperature indicates a temperature of the at least one of the electrical energy storage cells.

18. The circuit according to claim 1, wherein the electrically conductive terminal comprises an elongate conductive connection portion that is connected at a midway point on a perpendicular distal end so that at least two of the electrical energy storage cells have a same effect on a temperature reading by the temperature sensor.

19. The circuit according to claim 18, wherein the at least two of the electrical energy storage cells are spaced from a center axis of the elongate conductive connection portion by a same distance.

20. The circuit according to claim 18, wherein the at least two of the electrical energy storage cells have elongate bodies that extend parallel to a center axis of the elongate conductive connection portion by a same distance.
